(19) United States
(12) Patent Application Publication
(10) Pub. No.: US 2010/0308329 A1
(43) Pub. Date: Dec. 9, 2010

(54) LITHOGRAPHY ROBUSTNESS MONITOR

(75) Inventors: Harold Gerardus Pieter Hendrikus Benten, Waarle (NL); Agnese Antonietta Maria Bargagli-Stoffi, Eindhoven (NL); Hendricus Joseph Maria Veendrick, Heeze (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/864,614

(22) PCT Filed: Jan. 26, 2009
(86) PCT No.: PCT/IB09/50316

§ 371 Date: Jul. 26, 2010

Related U.S. Application Data
(60) Provisional application No. 61/023,934, filed on Jan. 28, 2008.

(51) Int. Cl. H01L 27/02; H01L 21/66; G06F 17/50

(52) U.S. Cl. 257/48; 438/18; 716/111; 257/E27.009; 257/E21.531

(57) ABSTRACT

The present invention relates to a method and device for monitoring a lithographic process of an integrated circuit. In a first step a design for an integrated circuit is provided. The integrated circuit comprises at least an integrated circuit transistor pair having a gate of a first transistor connected to a gate of a second transistor. The gate of the second transistor is designed such that it has a predetermined overlap with respect to a source and a drain of the second transistor. A detection circuit is connected to the at least an integrated circuit transistor pair for detecting if in operation functionality of the second transistor of each of the at least an integrated circuit transistor pair is one of a transistor and a short circuit. The integrated circuit is then manufactured in dependence upon the desogn. After manufacturing, the detection circuit is used to determine the functionality of the second transistor of each of the at least an integrated circuit transistor pair.

This invention relates generally to the field of integrated circuit design and manufacturing and more particularly to a method and device for monitoring a lithographic process used to fabricate an integrated circuit.

In state of the art Integrated Circuit (IC) manufacturing processes IC printing patterns with sub-wavelength resolution are employed which require compensation for aberrations in the patterning. Since the fabricated IC patterns are no longer an accurate replica of an originally designed IC pattern, masks used during lithography processes are corrected to compensate for these shortcomings using, for example, Optical Proximity Correction (OPC) during a mask definition process. For example, to improve imaging results Sub Resolution Assist Features (SRAFs), such as scattering bars and hammerheads, are used in the masks—which are not printed onto the wafer—to reduce resolution enhancement variations across the mask. Consequently, layout designers have to design the IC patterns such that enough space is left for adding OPC features and/or SRAFs and/or have to draw the IC pattern with constant proximity, making the design process substantially more complex.

For the time being, IC manufacturing processes still have to be based on 193 nm photolithography extended for use in sub 50 nm technologies such as, for example, state of the art Complementary Metal Oxide Semiconductor (CMOS) technologies. To improve yield, complex Design for Manufacturability (DfM) rules have already been used in technologies of less resolution. However, for sub 50 nm technologies the DfM rules are not sufficient and strict Design for Lithography (DfL) rules—also called litho-friendly design, litho-driven design, or litho-centric DfM—are applied, which focus on more regular layout structures. DfL simplifies the lithographic process and supports SRAFs.

The lithography process is a substantial source of variability—or mismatch—of components of an IC, for example, in analog IC designs that employ balanced pairs of transistors such as, for example, in differential amplifiers. The variations not only influence the transistor operation directly, but also influence the transistor's environment, which in itself is also a cause of variability. Of course, operation and performance of digital circuits are also influenced by the lithography process.

It would be highly desirable to provide a method and device for measuring the influence of the lithography on the functionality of the transistors to monitor lithographic robustness of an integrated circuit design.

In accordance with the present invention there is provided a lithography process monitor. The monitor comprises at least an integrated circuit transistor pair having a gate of a first transistor connected to a gate of a second transistor. The gate of the second transistor is designed such that it has a predetermined overlap with respect to a source and a drain of the second transistor. A detection circuit is connected to at least an integrated circuit transistor pair for detecting if in operation functionality of the second transistor of each of the at least an integrated circuit transistor pair is one of a transistor and a short circuit. In accordance with the present invention there is provided a method for monitoring a lithographic process. In a first step a design for an integrated circuit is provided. The integrated circuit comprises at least an integrated circuit transistor pair having a gate of a first transistor connected to a gate of a second transistor. The gate of the second transistor is designed such that it has a predetermined overlap with respect to a source and a drain of the second transistor. A detection circuit is connected to the at least an integrated circuit transistor pair for detecting if in operation functionality of the second transistor of each of the at least an integrated circuit transistor pair is one of a transistor and a short circuit. The integrated circuit is then manufactured in dependence upon the design. After manufacturing, the detection circuit is used to determine the functionality of the second transistor of each of the at least an integrated circuit transistor pair.

In accordance with the present invention there is further provided a storage medium having stored therein executable commands for execution on a processor. The processor when executing the commands performs steps for designing a lithography process monitor. The monitor comprises at least an integrated circuit transistor pair having a gate of a first transistor connected to a gate of a second transistor. The gate of the second transistor is designed such that it has a predetermined overlap with respect to a source and a drain of the second transistor. A detection circuit is connected to the at least an integrated circuit transistor pair for detecting if in operation functionality of the second transistor of each of the at least an integrated circuit transistor pair is one of a transistor and a short circuit.

Exemplary embodiments of the invention will now be described in conjunction with the following drawings, in which:

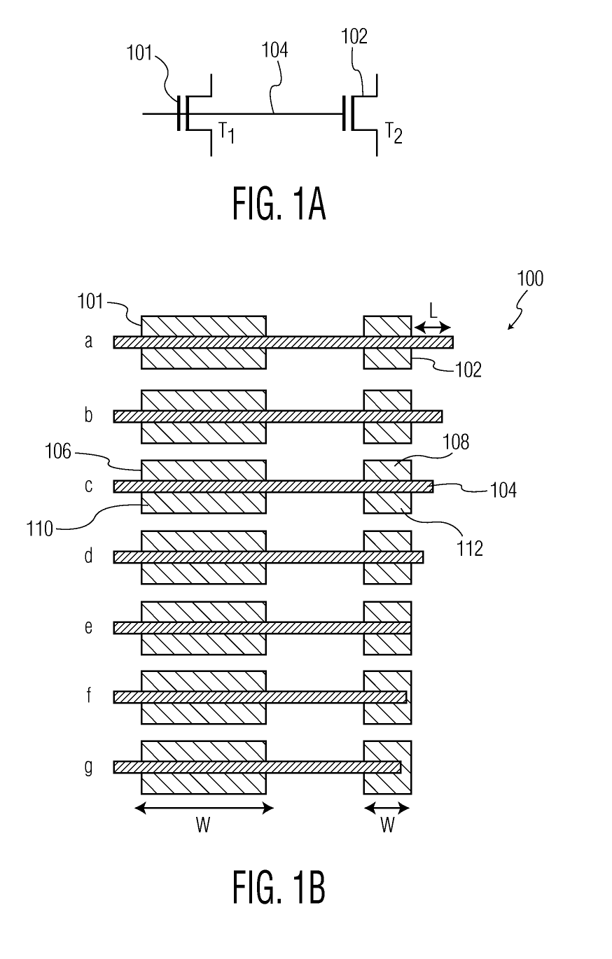

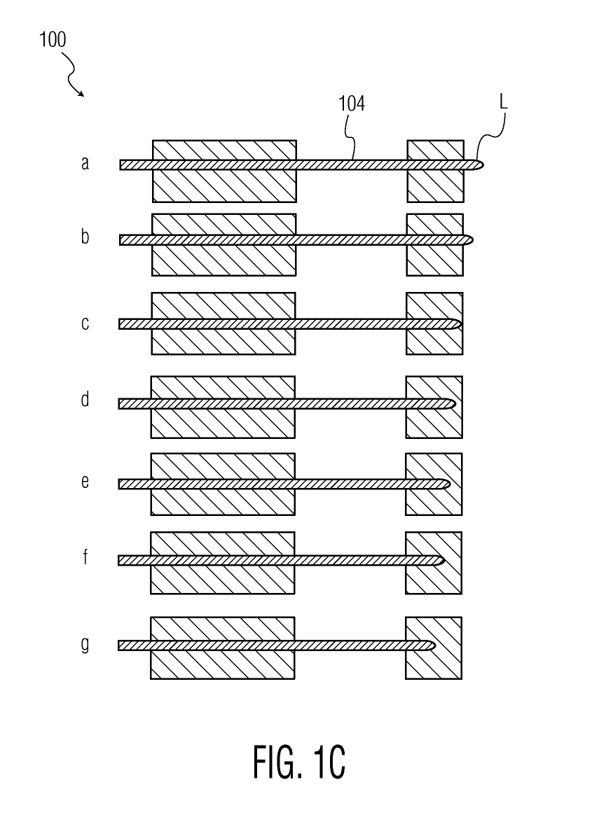

FIG. 1a is a simplified circuit diagram illustrating a lithography process monitor according to the invention;

FIGS. 1b and 1c are a simplified block diagrams illustrating an IC implementation of the monitor according to the invention;

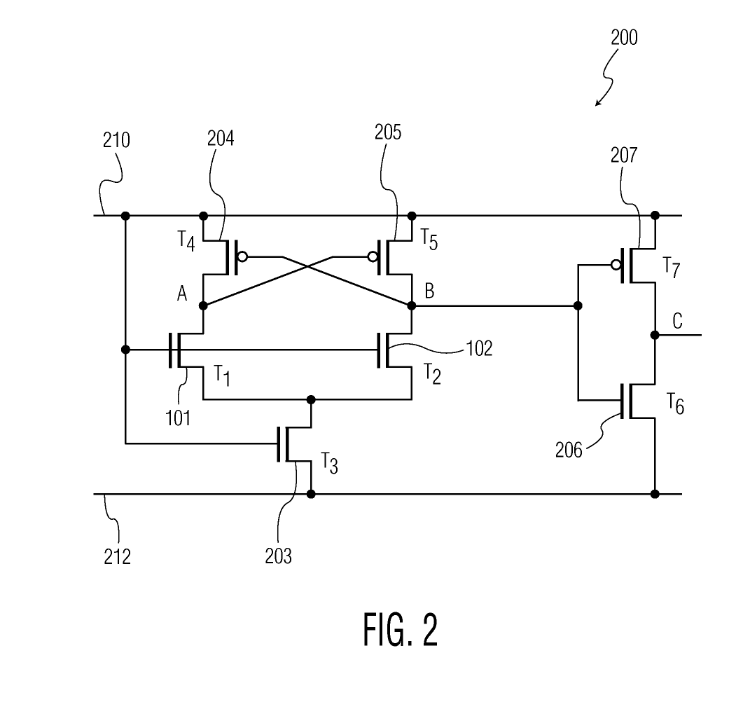

FIG. 2 is a simplified circuit diagram illustrating a detection circuit for use with the monitor shown in FIGS. 1a to 1c according to the invention;

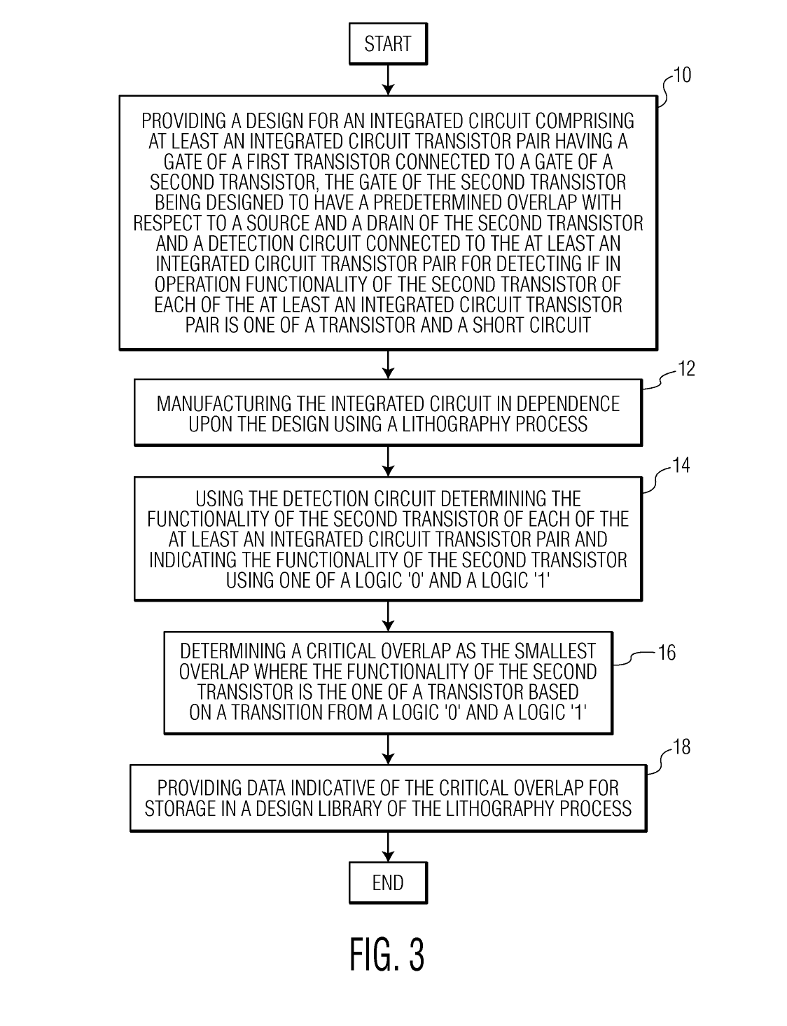

FIG. 3 is a simplified flow diagram illustrating a method for monitoring a lithographic process according to the invention; and,

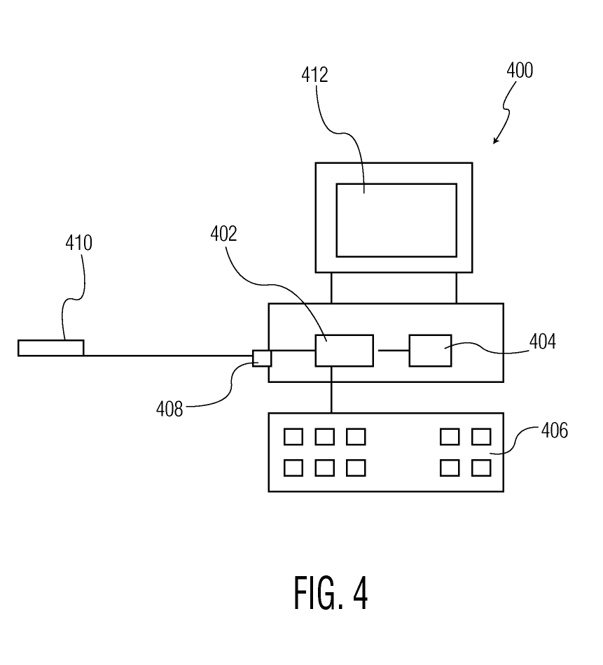

FIG. 4 is a simplified block diagram illustrating a system for performing the method for monitoring a lithographic process according to the invention.

The following description is presented to enable a person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the scope of the invention. Thus, the present invention is not intended to be limited to the embodiments disclosed, but is to be accorded the widest scope consistent with the principles and features disclosed herein.

While the invention will be described for the monitoring of the robustness of a photolithographic process for manufacturing ICs using CMOS technologies, it will become apparent to those skilled in the art that the invention is not limited thereto but is also applicable for various other ICs and other manufacturing methods where variability—or mismatch—of components is of concern.

Referring to FIGS. 1a to 1c, a lithography process monitor 100 according to the invention is shown, with FIG. 1a illustrating a circuit diagram of one transistor pair of the monitor 100, and FIGS. 1b and 1c illustrating N transistor pairs—labeled a through g—in an example embodiment of an IC implementation of the monitor 100. Each transistor pair comprises two NMOS transistors 101 and 102 with their gates being directly connected by gate 104. FIG. 1b illustrates the design layout of the N transistor pairs using CMOS technology. The transistors 101 and 102 each comprise a diffusion layer 106 and 108, respectively, forming a source, and a diffusion layer 110 and 112, respectively, forming a drain. The sources 106 and 108 are separated from the drains 110 and 112, respectively, by a gate layer 104—of, for example, polysilicon—extending from the first transistor 101 to the second transistor 102.

For each lithographic process, a minimum value for the gate overlap L is specified in a respective design rule manual. For example, in the design layout of the monitor 100 shown in FIG. 1b, the transistor pair c has the minimum specified overlap according to the design rule, while transistor pairs a and b have a larger overlap and transistor pairs d-g have smaller overlap. The reduction or extension of the overlap is, for example, done in a step wise fashion with a fixed or variable step size.

However, in the lithography process the gate layer 104 is not imaged ideally as illustrated in FIG. 1b, but the gate overlap L is rounded and substantially less than in the design layout, as illustrated in FIG. 1c. The purpose of the monitor 100 is to detect when the gate overlap L has become so small that in operation the transistor 102 has no longer the functionality of a transistor but one of a short circuit, i.e. the source 108 is directly connected to the drain 112. Based on the design layout illustrated in FIG. 1b, a short circuit is expected to start at transistor pair d or e, but based on the lithography process implementation illustrated in FIG. 1c, a short circuit is expected to already start at transistor pair c.

In order to practically use the monitor 100, the functionality of the second transistor 102—transistor function or short circuit—is detected electronically. Provision of an electronic detection circuit enables fast evaluation and easy read-out of the results. Referring to FIG. 2, an example implementation of a detection circuit 200 according to the invention is shown. The detection circuit comprises a differential input stage—transistors 101, 102, 203, 204, and 205—and a buffer—transistors 206 and 207. In the monitor 100, each transistor pair a to g—comprising transistors 101 and 102—is incorporated in the differential input stage of a respective detection circuit 200. In the example detection circuit the transistors 101 and 102 are NMOS transistors with the drain connected to a source of NMOS transistor 203 and the gate 104 connected to a positive supply voltage 210. A drain of the transistor 203 is connected to a negative supply voltage 212 and a gate of the transistor 203 is connected to the positive supply voltage 210. The sources of the transistors 101 and 102 are each connected to the positive supply voltage 210 via PMOS transistors 204 and 205, respectively. A gate of the transistor 204 is connected to node B interposed between the source of the transistor 102 and a drain of the transistor 205, while a gate of the transistor 205 is connected to node A interposed between the source of the transistor 101 and a drain of the transistor 204. The buffer comprises the PMOS transistor 207 having its source connected to the positive supply voltage 210 and its drain connected to a source of the NMOS transistor 206, which has its drain connected to the negative supply voltage 212. A gate of the transistor 206 and a gate of the transistor 207 are connected to the node B. Output node C is interposed between the drain of the transistor 207 and the source of the transistor 206. As is evident, there are numerous other solutions for a detection circuit applicable. For example, it is possible to connect the gate of the transistor 203—which acts as a current source—to a different voltage level. Alternatively, it is possible to use a complementary detection circuit to the one illustrated in FIG. 2 by replacing the PMOS devices with NMOS devices and vice versa.

In order to ensure proper operation of the detector circuit 200, the transistor 102 has a substantially smaller width to length ratio than the transistor 101, with width W as illustrated in FIG. 1b and the length being perpendicular to the plane illustrated in FIG. 1b. In case of the transistor functionality of the transistor 102 being the one as a transistor—i.e. the gate overlap of the transistor 102 is sufficient, the transistor 101 conducts substantially stronger than the transistor 102, therefore, the node A goes ‘low’ while the node B goes ‘high’, resulting in a logic ‘0’ at the output node C. In case of the transistor functionality of the transistor 102 being the one as a short circuit—i.e. the gate overlap of the transistor 102 is insufficient, the node B goes ‘low’ while the node A goes ‘high’, resulting in a logic ‘1’ at the output node C.

Referring to FIG. 3, a simplified flow diagram of a method for monitoring a lithographic process according to the invention is shown. At 10, a design of a monitor 100 according to the invention is provided. For example, a plurality of different overlaps is determined with each overlap corresponding to an integrated circuit transistor pair. One overlap is, for example, determined to be a minimum specified overlap according to a design rule of the lithography process. A plurality of overlaps larger than the minimum specified overlap and a plurality of overlaps smaller than the minimum specified overlap are determined in a stepwise fashion having a fixed or variable step size. After the design stage, respective masks for the lithography process are created and the integrated circuit is then manufactured using the lithography process—at 12. After manufacture, the detection circuit is used and the functionality of the second transistor of each of the at least an integrated transistor pair is determined and indicated using one of a logic ‘0’ and a logic ‘1’—at 14. A critical overlap is then determined as the smallest overlap where the functionality of the second transistor is the one of a transistor based on a transition from a logic ‘0’ to a logic ‘1’—at 16. Finally, at 18, data indicative of the critical overlap are provided for developing a standard-cell library or custom blocks in a certain lithography process.

Referring to FIG. 4, a simplified block diagram of a system for performing the method for monitoring a lithographic process according to the invention is shown. In practice, for example a ‘measurement setup’ or ‘production tester’ is incorporated into the system. The method for monitoring a lithographic process according to the invention is implemented, for example, using a processor 402 of a workstation 400. The design of the monitor 100 and the detection circuit 200 is performed by a user executing executable commands stored in a storage medium 404 and user interaction via keyboard 406 and graphical display 412 during the step of determining the functionality of the second transistor a wafer comprising the monitor and the detection circuit is connected via port 408 to the processor 402. The processor then receives the output data—logic ‘0’ and ‘1’—from the output nodes C and determines the critical overlap of the monitor and provides data indicative of the critical overlap of the lithography process used for developing a standard-cell library or custom blocks in a certain lithography process.

There are numerous possibilities for applying the method for monitoring a lithographic process according to the invention. For example, the method is applied during an initial phase of the creation of a design library of a new lithography process in order to provide an accurate indication for the critical overlap. Alternatively, the method is used to provide feedback about the quality of the lithographic process of a given wafer. For example, a processed wafer contains a plurality of chips which have to be separated using a sawing process. To avoid damaging of the chips during the sawing process a space called ‘scribe lane’ is interposed between the chips. It is customary to put Process Evaluation Monitors (PEMs) into the scribe lane for monitoring key process parameters, calibrating, tracking process parameters, and troubleshooting problems of the production process. It is possible to use the monitor 100 and detection circuit 200 as PEM disposed in the scribe lane for providing feedback about the quality of the lithography process of a specific wafer, or even a specific location on a specific wafer.

Numerous other embodiments of the invention will be apparent to persons skilled in the art without departing from the spirit and scope of the invention as defined in the appended claims.

What is claimed is:

1. A device comprising:
at least an integrated circuit transistor pair having a gate of a first transistor connected to a gate of a second transistor, the gate of the second transistor being designed to have a predetermined overlap with respect to a source and a drain of the second transistor; and,
a detection circuit connected to the at least an integrated circuit transistor pair for detecting if in operation functionality of the second transistor of each of the at least an integrated circuit transistor pair is one of a transistor and a short circuit.

2. A device as defined in claim 1 wherein the gate of the first transistor and the gate of the second transistor are formed as a single gate layer.

3. A device as defined in claim 2 wherein the second transistor of each of the at least an integrated circuit transistor pair has a different overlap.

4. A device as defined in claim 2 wherein one overlap is determined to be a minimum specified overlap according to a design rule of an integrated circuit manufacturing process.

5. A device as defined in claim 4 wherein at least one overlap is determined to be larger than the minimum specified overlap and at least one overlap is determined to be smaller than the minimum specified overlap.

6. A device as defined in claim 2 wherein the second transistor of each of the at least an integrated circuit transistor pair has a substantially smaller ratio of width to length than the first transistor.

7. A device as defined in claim 2 wherein the detection circuit for each of the at least an integrated circuit transistor pair comprises a differential input stage and a buffer.

8. A device as defined in claim 2 wherein the at least a transistor pair and the detection circuit are manufactured as a Complementary Metal Oxide Semiconductor (CMOS) integrated circuit.

9. A device as defined in claim 2 wherein the at least a transistor pair and the detection circuit are manufactured as an integrated circuit placed on a scribe lane of a semiconductor wafer.

10. A method comprising:
providing a design for an integrated circuit comprising:
at least an integrated circuit transistor pair having a gate of a first transistor connected to a gate of a second transistor, the gate of the second transistor being designed to have a predetermined overlap with respect to a source and a drain of the second transistor; and,
a detection circuit connected to the at least an integrated circuit transistor pair for detecting if in operation functionality of the second transistor of each of the at least an integrated circuit transistor pair is one of a transistor and a short circuit;
manufacturing the integrated circuit in dependence upon the design; and,
using the detection circuit determining the functionality of the second transistor of each of the at least an integrated circuit transistor pair.

11. A method as defined in claim 10 comprising indicating the functionality of the second transistor using one of a logic ‘0’ and a logic ‘1’.

12. A method as defined in claim 11 wherein the integrated circuit is manufactured using a lithography process.

13. A method as defined in claim 12 comprising determining a plurality of different overlaps, each overlap corresponding to an integrated circuit transistor pair.

14. A method as defined in claim 13 wherein one overlap is determined to be a minimum specified overlap according to a design rule of the lithography process.

15. A method as defined in claim 14 wherein at least one overlap is determined to be larger than the minimum specified overlap and at least one overlap is determined to be smaller than the minimum specified overlap.

16. A method as defined in claim 15 wherein a plurality of overlaps larger than the minimum specified overlap and a plurality of overlaps smaller than the minimum specified overlap are determined in a stepwise fashion.

17. A method as defined in claim 16 comprising determining a critical overlap as the smallest overlap where the functionality of the second transistor is the one of a transistor.

18. A method as defined in claim 17 wherein the critical overlap is determined based on a transition from a logic ‘0’ to a logic ‘1’.

19. A method as defined in claim 16 comprising providing data indicative of the critical overlap for storage in a design library of the lithography process.

20. A storage medium having stored therein executable commands for execution on a processor, the processor when executing the commands performing:
determining data indicative of a design for an integrated circuit comprising:
at least an integrated circuit transistor pair having a gate of a first transistor connected to a gate of a second transistor, the gate of the second transistor being designed to have a predetermined overlap with respect to a source and a drain of the second transistor; and,
a detection circuit connected to the at least an integrated circuit transistor pair for detecting if in operation functionality of the second transistor of each of the at least an integrated circuit transistor pair is one of a transistor and a short circuit.

21. A storage medium as defined in claim 20 having stored therein executable commands for execution on a processor, the processor when executing the commands performing:
determining a plurality of different overlaps, each overlap corresponding to an integrated circuit transistor pair.

22. A storage medium as defined in claim 21 having stored therein executable commands for execution on a processor, the processor when executing the commands performing:
receiving detection data from the detection circuit; and,
determining a critical overlap as the smallest overlap where the functionality of the second transistor is the one of a transistor.

23. A storage medium as defined in claim 22 having stored therein executable commands for execution on a processor, the processor when executing the commands performing:
providing data indicative of the critical overlap of the lithography process, or production method, used for developing a standard-cell library or custom analogue or digital blocks.
